(19) United States
(12) Patent Application Publication
(10) Pub. No.: US 2026/0086166 A1
(43) Pub. Date: Mar. 26, 2026

(54) Battery Diagnosis Apparatus and Operating Method Thereof

(71) Applicant: LG Energy Solution, Ltd., Seoul (KR)

(72) Inventors: Won Kyung Kim, Daejeon (KR); Jeong Bin Lee, Daejeon (KR); Sung Yul Yoon, Daejeon (KR); In Sik Kim, Daejeon (KR); Soon Jong Kim, Daejeon (KR); Ki Wook Kwon, Daejeon (KR); Young Seok Song, Daejeon (KR)

(21) Appl. No.: 19/202,636

(22) Filed: May 8, 2025

Related U.S. Application Data
(63) Continuation-in-part of application No. PCT/KR2023/015922, filed on Oct. 16, 2023.

(30) Foreign Application Priority Data
Nov. 11, 2022 (KR) 10-2022-0151069

(51) Int. Cl. G01R 31/392; G01R 19/00; G01R 19/12; G01R 19/165; G01R 31/36; G01R 31/367; G01R 31/3842; G01R 31/396; G01R 31/56

(52) U.S. Cl. CPC G01R 31/392; G01R 19/003; G01R 19/12; G01R 19/16528; G01R 31/3646; G01R 31/367; G01R 31/3842; G01R 31/396; G01R 31/56

(57) ABSTRACT

A battery diagnosis apparatus includes an obtaining unit configured to obtain first voltage values of a plurality of respective battery units, an identifying unit configured to identify second voltage values in different idle periods from among the first voltage values, a determining unit configured to determine a voltage gradient indicating a change degree of the second voltage values of the plurality of respective battery units over time and determine a standard score (Z-score) of the voltage gradient for each of the plurality of battery units by using an average and a standard deviation of a plurality of voltage gradients one-to-one corresponding to the plurality of battery units, and a diagnosing unit configured to select, from among the plurality of battery units, a battery unit having the standard score outside of a first reference range and the voltage gradient outside of a second reference range and diagnose at least some of selected battery units as abnormal battery units.

### CROSS-REFERENCE TO RELATED APPLICATION

This application is a bypass continuation-in-part of International Application No. PCT/KR2023/015922 filed Oct. 16, 2023, which claims priority to and the benefit of Korean Patent Application No. 10-2022-0151069 filed in the Korean Intellectual Property Office on Nov. 11, 2022, the entire content of which is incorporated herein by reference.

### TECHNICAL FIELD

Embodiments disclosed herein relate to a battery diagnosis apparatus and an operating method thereof.

### BACKGROUND ART

Recently, research and development of secondary batteries have been actively performed. Herein, the secondary batteries, which are chargeable/dischargeable batteries, may include all of conventional nickel (Ni)/cadmium (Cd) batteries, Ni/metal hydride (MH) batteries, etc., and recent lithium-ion batteries. Among the secondary batteries, a lithium-ion battery has a much higher energy density than those of the conventional Ni/Cd batteries, Ni/MH batteries, etc. Moreover, the lithium-ion battery may be manufactured to be small and lightweight, such that the lithium-ion battery has been used as a power source of mobile devices, and recently, a use range thereof has been extended to power sources for electric vehicles, attracting attention as next-generation energy storage media.

Furthermore, the secondary battery may be used as a battery pack including a battery module where a plurality of battery cells are connected to one another in series and/or in parallel. The secondary battery may be used as a battery rack including a plurality of battery modules and a rack frame receiving the battery modules.

The battery cell, the battery module, the battery pack, or the battery rack may be used in various devices. For example, the batteries may be used not only for mobile devices such as mobile phones, laptop computers, smart phones, smart pads, etc., but also in the field of vehicles (EV, HEV, PHEV) driven with electricity, large-volume energy storage systems (ESS), etc.

These batteries may be managed and controlled in terms of states and operations thereof by a battery management system (BMS). The battery management system may be included together with one or more batteries in one or more devices. Alternatively, the battery management system may manage and control the one or more batteries remotely without being included in the one or more devices.

### SUMMARY

### Technical Problem

When a short circuit or a failure of another type occurs inside a battery, the possibility of damage to devices (e.g., EV, ESS) including the battery may increase.

Accordingly, there is a need for a scheme to reduce the possibility of damage to devices including a battery by detecting an abnormal state of the battery due to short circuit or other types of failures.

Technical problems of the embodiments disclosed herein are not limited to the above-described technical problems, and other unmentioned technical problems would be clearly understood by one of ordinary skill in the art from the following description.

### Technical Solution

A battery diagnosis apparatus according to an embodiment disclosed herein includes a processor and memory having instructions programmed thereon, wherein the instructions are configured to cause the processor to obtain respective first voltage values of a plurality of battery units, identify second voltage values in different idle periods from among the first voltage values, for each battery unit of the plurality of battery units determine a voltage gradient indicating a change degree of the second voltage values of the battery unitover time determine a Z-score of the voltage gradient for the battery unit based on an average and a standard deviation of the determined plurality of voltage gradients of the plurality of battery units, and based on the Z-score of the battery unit being outside of a first reference range and the voltage gradient outside of a second reference range, diagnose the battery unit as an abnormal battery unit.

In the battery diagnosis apparatus according to an embodiment disclosed herein, the instructions may be configured to cause the processor to for each battery unit of the plurality of battery units determine an average voltage value of the idle periods of the battery unit, based on the second voltage values of the battery unit and determine the voltage gradient based on the average voltage value.

In the battery diagnosis apparatus according to an embodiment disclosed herein, the instructions may be configured to cause the processor to based on the battery unit having the Z-score greater than a first upper limit of the first reference range and the voltage gradient greater than a second upper limit of the second reference range, diagnose the battery unit as the abnormal battery unit, when the idle periods of the battery unit are after respective charging periods of the battery unit.

In the battery diagnosis apparatus according to an embodiment disclosed herein, the instructions may be configured to cause the processor to based on the battery unit having the Z-score less than a first lower limit of the first reference range and the voltage gradient less than a second lower limit of the second reference range, diagnose the battery unit as the abnormal battery unit, when the idle periods of the battery unit are after respective discharging periods of the battery unit.

In the battery diagnosis apparatus according to an embodiment disclosed herein, the instructions may be configured to cause the processor to diagnose the battery unit as the abnormal battery unit, based on a difference between a maximum value and a minimum value of the second voltage values of the battery unit being greater than a designated difference value.

In the battery diagnosis apparatus according to an embodiment disclosed herein, the instructions may be configured to cause the processor to set the idle periods as periods of time for which respective ones of the plurality of battery units have one or more of voltage values, current values, amounts of charge, or amounts of discharge within respective designated ranges.

In the battery diagnosis apparatus according to an embodiment disclosed herein, the instructions may be configured to cause the processor to perform an abnormality processing function, in which the abnormality processing function includes a notification function or an isolation function.

A battery diagnosis method according to an embodiment disclosed herein includes obtaining respective first voltage values of a plurality of respective battery units, identifying second voltage values in different idle periods from among the first voltage values, for each battery unit of the plurality of battery units determining a voltage gradient indicating a change degree of the second voltage values of the battery unitover time, determining a Z-score of the voltage gradient for the battery unit based on an average and a standard deviation of the determined plurality of voltage gradients of the plurality of battery units, based on the Z-score outside of a first reference range and the voltage gradient outside of a second reference range, diagnosing the battery unit as an abnormal battery unit.

The battery diagnosis method according to an embodiment disclosed herein may include, for each battery unit of the plurality of battery units, determining an average voltage value of the idle periods of the battery unit, based on the second voltage values of the battery unit and determining the voltage gradient based on the average voltage value.

In the battery diagnosis method according to an embodiment disclosed herein, when the idle periods of the battery unit are after charging periods of the battery unit, diagnosing the battery unit as an abnormal battery unit may be based on the Z-score being greater than a first upper limit of the first reference range and the voltage gradient being greater than a second upper limit of the second reference range.

The battery diagnosis method according to an embodiment disclosed herein, when the idle periods of the battery unit are after discharging periods of the battery unit diagnosing the battery unit as an abnormal battery unit may be based on the Z-score being less than a first lower limit of the first reference range and the voltage gradient being less than a second lower limit of the second reference range.

In the battery diagnosis method according to an embodiment disclosed herein, the diagnosing of the battery unit as abnormal may be based on a difference between a maximum value and a minimum value of the second voltage values of the battery unit being greater than a designated difference value.

The battery diagnosis method according to an embodiment disclosed herein may further include setting the idle periods as periods of time for which respective ones of the plurality of battery units have one or more of voltage values, current values, amounts of charge, or amounts of discharge within respective designated ranges.

The battery diagnosis method according to an embodiment disclosed herein may further include for each battery unit diagnosed as abnormal performing an abnormality processing function, in which the abnormality processing function includes a notification function or an isolation function.

A non-transitory computer-readable storage medium according to an embodiment disclosed herein has stored therein instructions that, when executed by one or more processors, cause the one or more processors to perform operations comprising: obtaining respective first voltage values of a plurality of respective battery units; identifying second voltage values in different idle periods from among the first voltage values; for each battery unit of the plurality of battery units: determining a voltage gradient indicating a change degree of the second voltage values of the battery unit over time; determining a Z-score of the voltage gradient for the battery unit based on an average and a standard deviation of the determined plurality of voltage gradients of the plurality of battery units; and based on the Z-score outside of a first reference range and the voltage gradient outside of a second reference range, diagnosing the battery unit as an abnormal battery unit.

According to an embodiment, determining of the voltage gradient may include for each battery unit of the plurality of battery units: determining an average voltage value of the idle periods of the battery unit, based on the second voltage values of the battery unit and determining the voltage gradient based on the average voltage value.

According to an embodiment, when the idle periods of the battery unit are after charging periods of the battery unit, diagnosing the battery unit as an abnormal battery unit may be based on the standard score being greater than a first upper limit of the first reference range and the voltage gradient being greater than a second upper limit of the second reference range.

According to an embodiment, when the idle periods of the battery unit are after discharging periods of the battery unit, diagnosing the battery unit as an abnormal battery unit may be based on the Z-score being less than a first lower limit of the first reference range and the voltage gradient being less than a second lower limit of the second reference range.

According to an embodiment, diagnosing of the battery unit as abnormal may be based on a difference between a maximum value and a minimum value of the second voltage values of the battery unit being greater than a designated difference value.

According to an embodiment, diagnosing of the battery unit as abnormal may be based on a difference between a maximum value and a minimum value of the second voltage values of the battery unit being greater than a designated difference value.

### Advantageous Effects

A battery diagnosis apparatus and an operating method thereof according to various embodiments disclosed herein may detect occurrence of a short circuit or a failure of another type inside a battery.

A battery diagnosis apparatus and an operating method thereof according to various embodiments disclosed herein may process the detected short circuit or failure of another type inside the battery.

The effects of the battery abnormality diagnosis apparatus and the operating method thereof according to the disclosure of the present document are not limited to the effects mentioned above, and other effects not mentioned will be clearly understood by those of ordinary skill in the art according to the disclosure of the present document.

Moreover, various effects recognized directly or indirectly from the disclosure may be provided.

### BRIEF DESCRIPTION OF THE DRAWINGS

FIG. 1 shows graphs of a difference between a voltage change degree of a normal battery unit and a voltage change degree of an abnormal battery unit in idle periods.

FIG. 2 is a block diagram of a battery diagnosis apparatus according to an embodiment.

FIG. 3A is a graph showing an example where an idle period is set after charging of a battery unit, according to an embodiment.

FIG. 3B is a graph showing an example where an idle period is set after discharging of a battery unit, according to an embodiment.

FIG. 4 is a graph showing an example where abnormality is diagnosed based on a standard score (Z-score) of a battery unit, according to an embodiment.

FIG. 5 is an operating flowchart of a battery diagnosis apparatus according to an embodiment.

FIG. 6 is an operating flowchart of a battery diagnosis apparatus according to an embodiment.

### DETAILED DESCRIPTION

Hereinafter, various embodiments of the present disclosure will be disclosed with reference to the accompanying drawings. However, the description is not intended to limit the present disclosure to particular embodiments, and it should be construed as including various modifications, equivalents, and/or alternatives according to the embodiments of the present disclosure.

It should be appreciated that various embodiments of the present document and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. Such terms as “1^{st}”, “2^{nd},” “first”, “second”, “A”, “B”, “(a)”, or “(b)” may be used to simply distinguish a corresponding component from another, and does not limit the components in other aspect (e.g., importance or order), unless mentioned otherwise.

Herein, it is to be understood that when an element (e.g., a first element) is referred to, with or without the term “operatively” or “communicatively”, as “connected with”, “coupled with”, or “linked with”, or “coupled to” or “connected to” to another element (e.g., a second element), it means that the element may be connected with the other element directly (e.g., wiredly), wirelessly, or via a third element.

According to an embodiment of the disclosure, a method according to various embodiments of the disclosure disclosed herein may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

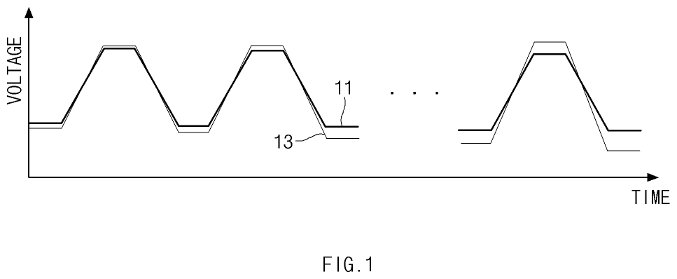

FIG. 1 is a graph showing a difference between an amount of voltage change of a normal battery unit between idle periods of the normal battery unit, and an amount of voltage change of an abnormal battery unit between idle periods of the abnormal battery unit.

Referring to FIG. 1, a graph 10 showing a voltage 11 of a normal battery unit and a voltage 13 of an abnormal battery unit may be seen. The voltage of the battery units is shown as rising during charging of the battery units, and falling during discharging of the battery units. In the graph 10, the voltage of the battery units is shown as being maintained at a relatively constant value during idle periods of the battery after the charging and after the discharging. In the case of the normal battery unit, after a charging and discharging cycle of the normal battery unit, it may be seen from the graph 10 that the change in the voltage 11 of the normal battery unit, referred to herein as a voltage value difference, is relatively small. On the other hand, in the case of the abnormal battery unit, after each charging and discharging cycle of the abnormal battery unit, it may be seen from the graph 10 that the change in the voltage 13 of the abnormal battery unit is comparatively large in each of the idle periods. For example, for the voltage 13 of the abnormal battery unit, the voltage value of the abnormal battery during an idle period after one charging period may rise significantly as compared to the voltage value of the abnormal battery during the idle period after the previous charging period. The voltage value of the abnormal battery during idle periods after charging may continue to rise as the charging and discharging cycles continue. For further example, for the voltage 13 of the abnormal battery unit, the voltage value of the abnormal battery during an idle period after one discharging period may drop significantly as compared to the voltage value of the abnormal battery during the idle period after the previous discharging period. The voltage value of the abnormal battery during idle periods after discharging may continue to drop as the charging and discharging cycles continue. When a short circuit or a failure of another type occurs inside a battery unit, an abnormal behavior like the voltage 13 of the abnormal battery unit may appear.

As such, damage to an electronic device may occur due to the battery unit showing the abnormal behavior like the voltage 13 of the abnormal battery unit. This may be because an actual voltage of the battery unit may be higher than an expected voltage of the battery unit during idle periods after charging, or lower than an expected voltage of the battery unit during idle periods after discharging. Thus, it may be advantageous for a battery unit having an abnormal behavior to be detected from among battery units, and to be appropriately processed, such as by changing a state of operation of the battery unit, indicating that the battery unit is ready for replacement, or both.

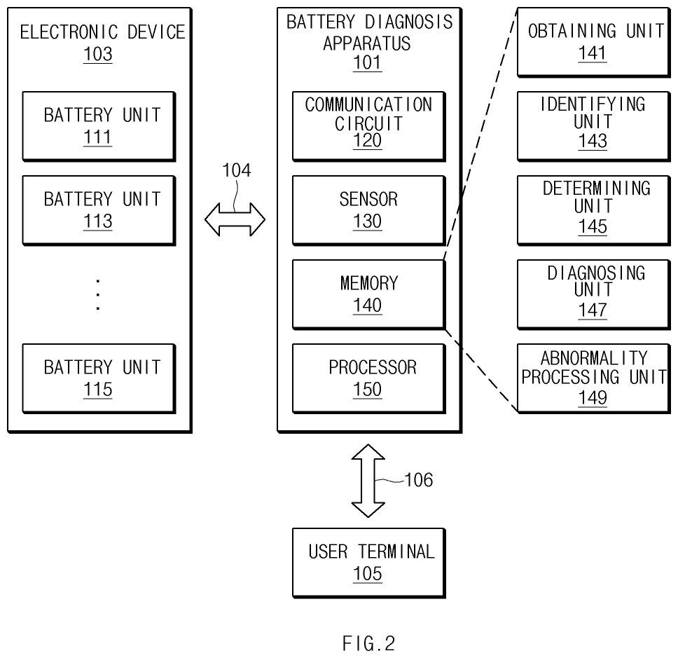

FIG. 2 is a block diagram of a battery diagnosis apparatus according to an embodiment.

Referring to FIG. 2, the battery diagnosis apparatus 101 may be wiredly and/or wirelessly connected to an electronic device 103 and a user terminal 105.

In an embodiment, connection 104 between the battery diagnosis apparatus 101 and the electronic device 103 may be communication connection through a wired and/or wireless network. In an embodiment, the wired network may be based on a local area network (LAN) communication or a power-line communication. In an embodiment, the wireless network may be based on a short-range communication network (e.g., Bluetooth, Wireless Fidelity (WiFi), or Infrared Data Association (IrDA)) or a remote-range communication network (e.g., a cellular network, a 4^{th}-Generation (4G) network, a 5^{th}-Generation (5G) network).

In another embodiment, the connection 104 between the battery diagnosis apparatus 101 and the electronic device 103 may be connection using a device-to-device communication scheme (e.g., a bus, a general-purpose input and output (GPIO), a serial peripheral interface (SPI), or a mobile industry processor interface (MIPI)).

In an embodiment, connection 106 between the battery diagnosis apparatus 101 and the user terminal 105 may be communication connection through a wired and/or wireless network.

In an embodiment, the electronic device 103 may be a mobile device (e.g., a mobile phone, a laptop computer, a smart phone, a smart pad), en electric vehicle (e.g., an electric vehicle (EV), a hybrid EV (HEV), a plug-in HEV (PHEV), a fuel cell EV (FCEV)), an energy storage system (ESS), or a battery swapping system (BSS).

In an embodiment, the electronic device 103 may include one or more battery units 111, 113, and 115. Each of the one or more battery units 111, 113, and 115 may be a battery cell, a battery module, a battery pack, or a battery rack.

In an embodiment, the user terminal 105 may be a mobile device (e.g., a mobile phone, a laptop computer, a smart phone, a smart pad), or a personal computer (PC).

In an embodiment, the battery diagnosis apparatus 101 may include a communication circuit 120, a sensor 130, a memory 140, and a processor 150. According to an embodiment, the battery diagnosis apparatus 101 shown in FIG. 2 may further include at least one component (e.g., a display, an input device, or an output device) in addition to components shown in FIG. 2.

In an embodiment, the communication circuit 120 may establish a wired communication channel and/or a wireless communication channel between the battery diagnosis apparatus 101 and the electronic device 103 and/or the user terminal 105, and transmit and receive data to and from the electronic device 103 and/or the user terminal 105 through the established communication channel.

In an embodiment, the sensor 130 may obtain values related to states of the battery units 111, 113, and 115 of the electronic device 103. In an embodiment, the values related to the states, also referred to herein as ‘state values’, may indicate one or more values of voltages, currents, resistances, states of charge (SoC), states of health (SoH), or temperatures of the battery units 111, 113, and 115 or combinations thereof. For example, the sensor 130 can sense one or both of a voltage or a current of a given battery unit to collect information showing charging periods, discharging periods, and idle periods of the battery unit, as well as the relative voltage values of the battery unit during the charging, discharging and idle periods. In this regard, it should be understood that the voltage change values described herein may be derived using measurements from the sensor 130. It should also be understood that while FIG. 2 shows a single box labelled “sensor 130,” the apparatus may include multiple sensors, such as a respective voltage sensor or a respective current sensor for each battery module, or a respective voltage sensor or a respective current sensor for respective groups of the battery modules.

In an embodiment, the memory 140 may include a volatile and/or a nonvolatile memory.

In an embodiment, the memory 140 may store data used by at least one component (e.g., the processor 150) of the battery diagnosis apparatus 101. For example, the data may include software (or an instruction related thereto), input data, or output data. In an embodiment, the instruction, when executed by the processor 150, may cause the battery abnormality diagnosis apparatus 101 to perform operations defined by the instruction.

In an embodiment, the memory 140 may include one or more software programs (e.g., an obtaining unit 141, an identifying unit 143, a determining unit 145, a diagnosing unit 147, and an abnormality processing unit 149).

In an embodiment, the processor 150 may include any one or combination of a central processing unit, an application processor, a graphic processing unit, a neural processing unit (NPU), an image signal processor, a sensor hub processor, or a communication processor.

In an embodiment, the processor 150 may execute one or more software programs included in the memory 140, including but not limited to the obtaining unit 141, the identifying unit 143, the determining unit 145, the diagnosing unit 147, and the abnormality processing unit 149. The software programs may be executed to control other hardware components, software components, or both, to perform various data processing or operations. One or more of the hardware and/or software components may be included within the battery diagnosis apparatus 101 that includes the processor 150. Additionally or alternatively, one or more of the hardware and/or software components may be situated remotely from, but communicatively connected to, the battery diagnosis apparatus 101.

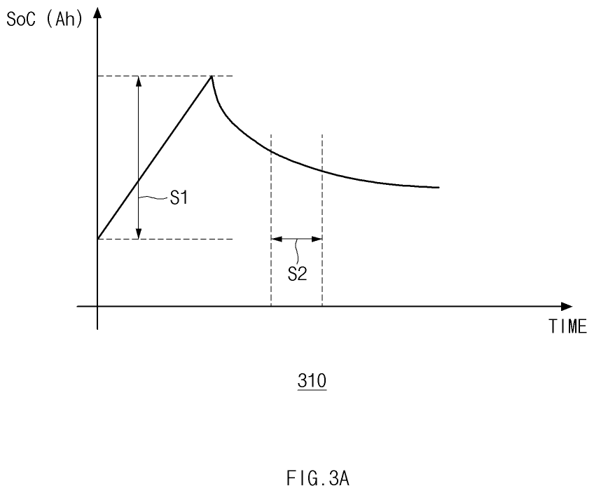

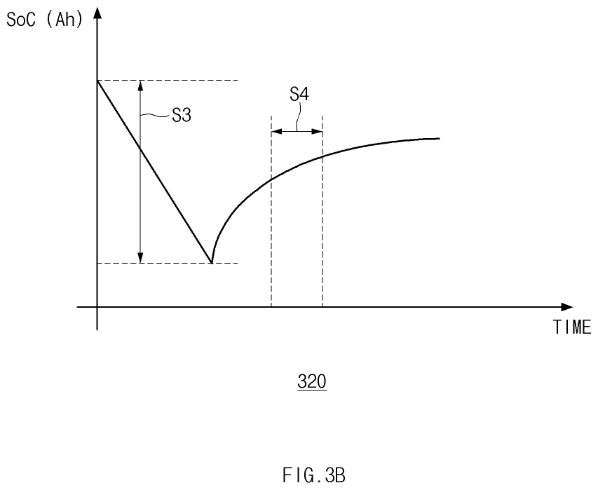

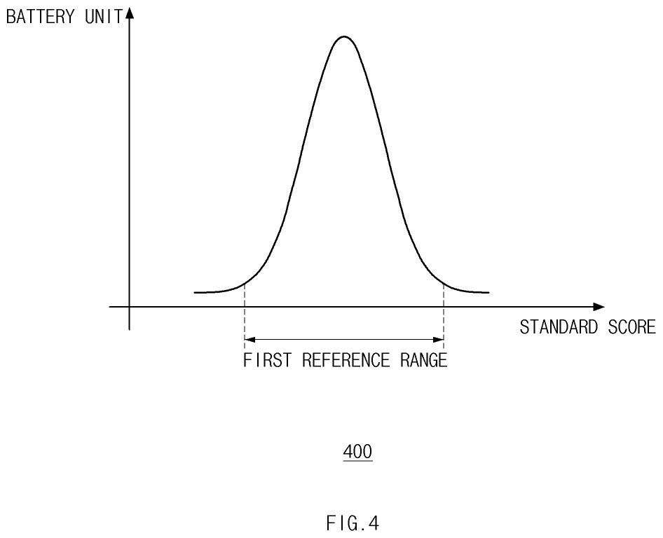

Hereinbelow, referring to FIGS. 3A, 3B, and 4, a description will be made of a method, performed by the battery diagnosis apparatus 101, of diagnosing abnormality of the battery units 111, 113, and 115 through the obtaining unit 141, the identifying unit 143, the determining unit 145, the diagnosing unit 147, and/or the abnormality processing unit 149.

FIG. 3A is a graph showing an example where an idle period is set after charging of a battery unit, according to an embodiment. FIG. 3B is a graph showing an example where an idle period is set after discharging of a battery unit, according to an embodiment. FIG. 4 is a graph showing an example where abnormality is diagnosed based on a standard score (Z-score) of a battery unit, according to an embodiment. FIGS. 3A, 3B, and 4 will be described using the components of FIG. 2.

In an embodiment, the obtaining unit 141 may obtain first voltage values of the plurality of respective battery units 111, 113, and 115. In an embodiment, the obtaining unit 141 may obtain a plurality of voltage profiles, each voltage profile respectively indicating voltage changes over time of a respective battery unit among the plurality of battery units 111, 113, and 115. In such an embodiment, the obtaining unit 141 may obtain the first voltage values based on the obtained plurality of voltage profiles.

In an embodiment, the obtaining unit 141 may obtain the first voltage values of the plurality of respective battery unit 111, 113, and 115 through the electronic device 103 connected through a wired and/or wireless network.

In an embodiment, the identifying unit 143 may identify second voltage values from among the first voltage values. Each identified second voltage value may belong to a different respective idle period, such as each second voltage value belonging to a respective idle period after charging or each second voltage value belonging to a respective idle period after discharging. In an embodiment, the identifying unit 143 may determine that the second voltage values belong to idle periods by identifying the idle periods based on the first voltage values. For example, idle periods may be identified as values among the first voltage values having voltage values, current values, the amounts of charge, and/or the amounts of discharge in designated ranges. The identifying unit 143 may extract the different idle periods for each of the plurality of battery units 111, 113, and 115 from the obtained plurality of voltage profiles, and identify the second voltage values in the corresponding periods for the plurality of respective battery units 111, 113, and 115.

In an embodiment, the different idle periods may all be idle periods after different charging periods. In another embodiment, the different idle periods may all be idle periods after different discharging periods.

For example, referring to FIG. 3A, a charging period S1 and an idle period S2 after charging may be seen from the graph 310. In an embodiment, the identifying unit 143 may identify the charging period S1 having a designated amount of charging from the plurality of SOC profiles of the plurality of respective battery units 111, 113, and 115. To this end, the obtaining unit 141 may obtain the plurality of SOC profiles of the plurality of respective battery unit 111, 113, and 115 through the electronic device 103 connected through a wired and/or wireless network. In an embodiment, the identifying unit 143 may extract the idle period S2 after charging, based on a voltage value and/or a current value of each of the plurality of battery units 111, 113, and 115 after the charging period S1. For example, the identifying unit 143 may extract, as the idle period S2 after charging, a period in which the current value of the battery unit 111, 113, or 115 is in a first current range (e.g., a range of 0 A to 1 A).

In another example, referring to FIG. 3B, a discharging period S3 and an idle period S4 after discharging may be seen from a graph 320. In an embodiment, the identifying unit 143 may identify the discharging period S3 having a designated amount of discharging from the plurality of SOC profiles of the plurality of respective battery units 111, 113, and 115. In an embodiment, the identifying unit 143 may extract the idle period S4 after discharging, based on a voltage value and/or a current value of each of the plurality of battery units 111, 113, and 115 after the discharging period S3. For example, the identifying unit 143 may extract, as the idle period S2 after charging, a period in which the current value of the battery unit 111, 113, or 115 is in a second current range (e.g., a range of −1 A to 0 A).

In an embodiment, the identifying unit 143 may identify the second voltage values of the plurality of respective battery units 111, 113, and 115 in the extracted different idle periods (e.g., different idle periods after charging or different idle periods after discharging).

In an embodiment, the determining unit 145 may determine a voltage gradient of the second voltage values of the plurality of respective battery units 111, 113, and 115 over time. In an embodiment, the determining unit 145 may determine average voltage values of different idle periods (e.g., idle periods after different charging periods or idle periods after different discharging periods) of each of the plurality of battery units 111, 113, and 115, based on the second voltage values. The determining unit 145 may determine the voltage gradient based on the average voltage values. For example, the determining unit 145 may determine the average voltage values of the idle periods after different charging periods for the plurality of respective battery units 111, 113, and 115, as shown in Table 1 below.

TABLE 1

Battery Unit

| Idle Period | 111 | 113 | . . . | 115 |
|---|---|---|---|---|
| Idle Period | 4.0514 | 4.0502 | . . . | 4.0531 |
| after First Charging | | | | |
| Idle Period | 4.0513 | 4.0528 | . . . | 4.0531 |
| after Second Charging | | | | |
| Idle Period | 4.0513 | 4.0566 | . . . | 4.0530 |
| after Third Charging | | | | |

Referring to [Table 1], an average voltage of the battery unit 111 is maintained constant such as 4.0514, 4.0513, and 4.0513 even when idle periods after charging continue, whereas an average voltage of the battery 113 relatively rises such as 4.0502, 4.5028, and 4.0566 as the idle periods after charging continue.

In another example, the determining unit 145 may determine the average voltage values of the idle periods after different discharging periods for each of the plurality of battery units 111, 113, and 115, as shown in Table 2 below.

TABLE 2

Battery Unit

| Idle Period | 111 | 113 | . . . | 115 |
|---|---|---|---|---|
| Idle Period | 3.5122 | 3.5125 | . . . | 3.5122 |
| after First Discharging | | | | |
| Idle Period | 3.5122 | 3.5157 | . . . | 3.5122 |
| after Second Discharging | | | | |
| Idle Period | 3.5122 | 3.5191 | . . . | 3.5122 |
| after Third Discharging | | | | |

Referring to [Table 2], an average voltage of the battery unit 111 is maintained constant such as 3.5122, 3.5122, and 3.5122 even when idle periods after discharging continue, whereas an average voltage of the battery 113 relatively rises such as 3.5125, 3.5157, and 3.5191 as the idle periods after discharging continue.

In an embodiment, the determining unit 145 may determine the voltage gradient based on a linear regression scheme. For example, the determining unit 145 may determine a plurality of voltage gradients for the plurality of respective battery units 111, 113, and 115 based on the linear regression scheme by using all of the second voltage values of the plurality of respective battery units 111, 113, and 115 as input factors. In another example, the determining unit 145 may determine the plurality of voltage gradients based on the linear regression scheme by using, as input factors, average voltage values in different idle periods of each of the plurality of battery units 111, 113, and 115.

In an embodiment, the determining unit 145 may determine a Z-score, also referred to herein as a standard score, of a voltage gradient for each of the plurality of battery units 111, 113, and 115 by using an average and a standard deviation of the plurality of voltage gradients one-to-one corresponding to the plurality of battery units 111, 113, and 115. For example, the determining unit 145 may determine the standard score according to Equation 1.

$$z = \frac{x - μ}{σ} \qquad [ Equation 1 ]$$

In Equation 1, z indicates a standard score of a voltage gradient of the battery unit 111, 113, or 115, x indicates a voltage gradient of the battery unit 111, 113, or 115, μ indicates an average of a plurality of voltage gradients one-to-one corresponding to the plurality of battery units 111, 113, and 115, and σ indicates a standard deviation.

In an embodiment, the diagnosing unit 147 may select, from among the plurality of battery units 111, 113, and 115, a battery unit that has the standard score outside of a first reference range and has the voltage gradient outside of a second reference range. For example, referring to FIG. 4, the diagnosing unit 147 may diagnose all battery units having a standard score outside of the first reference range of a graph 400 as abnormal battery units.

For example, when the different idle periods are idle periods after different charging periods, the diagnosing unit 147 may select, from among the plurality of battery units 111, 113, and 115, a battery unit that has a standard score greater than a first upper limit of the first reference range and has a voltage gradient greater than a second upper limit of the second reference range.

In another example, when the different idle periods are idle periods after different charging periods, the diagnosing unit 147 may select, from among the plurality of battery units 111, 113, and 115, a battery unit that has a standard score less than a first lower limit of the first reference range and has a voltage gradient less than a second lower limit of the second reference range.

In an embodiment, the diagnosing unit 147 may diagnose at least some of the selected battery units as abnormal battery units. In an embodiment, the diagnosing unit 147 may diagnose as an abnormal battery unit, among the selected battery units, a battery unit in which a difference between a maximum value and a minimum value of the second voltage values is greater than a designated difference value.

In an embodiment, the diagnosing unit 147 may diagnose abnormality of a battery unit based on a voltage gradient, a standard score of the voltage gradient, and a difference between a maximum value and a minimum value, for each of the plurality of battery units 111, 113, and 115, as shown in Table 3.

TABLE 3

| | Battery Unit | | | |
|---|---|---|---|---|
| | 111 | 113 | . . . | 115 |
| Voltage Gradient | 0.000231 | −0.003 | . . . | 0.0002 |
| Standard Score of | 0.27735 | −3.6055 | . . . | 0.27735 |
| Voltage Gradient | | | | |
| Difference | 0.013 | 0.045 | . . . | 0.013 |
| between Maximum Value | | | | |
| and Minimum Value | | | | |

For example, when the different idle periods are idle periods after discharging, the first reference range is from −3 to 3, the second reference range is from −0.01 to 0.01, and a designated difference is 0.04, then the battery unit 113 of Table 3 has a standard score of −3.6055 outside of the first reference range, a voltage gradient of −0.003 outside of the second reference range, and a difference of 0.045 between a maximum value and a minimum value, greater than a designated difference value, such that the diagnosing unit 147 may diagnose the battery unit 113 as an abnormal battery unit.

In an embodiment, the abnormality processing unit 149 may perform an abnormality processing function based on abnormality diagnosis results for the plurality of battery units 111, 113, and 115. In an embodiment, the abnormality processing function may include a notification function or a short circuit function.

For example, in performing the notification function, the abnormality processing unit 147 may transmit a notification containing the abnormality diagnosis results of the plurality of battery units 111, 113, and 115 to the user terminal 105 connected through a wired and/or wireless network.

In another embodiment, in performing the short circuit function, the abnormality processing unit 149 may respond to the detected presence of a short circuit by performing an isolation function that isolates the abnormality battery unit from the electronic device 103 based on the abnormality diagnosis results of the plurality of battery units 111, 113, and 115. Herein, isolation may include electrical and/or mechanical isolation. Electrical isolation may involve controlling a switch connected to an electrical path between the abnormal battery unit and the electronic device 103 in a manner that electrically disconnects the abnormal battery unit from the electronic device 103. Such a switch may be a relay positioned on the electrical path, whereby opening the relay results in electrical disconnection along the electrical path. Alternatively, the switch may be a branch from the electrical path, such as a short to ground or additional circuitry that effectively electrically disconnects the abnormal battery unit from the electronic device 103. Mechanical isolation may also result in electrical disconnection along the electrical path, but may further involve a mechanical component to facilitate the electrical disconnection. For instance, a fuse may be used to disconnect the electrical path between the abnormal battery unit and the electronic device 103. Alternatively, a switch may include one or more mechanical components that physically move or change position to disconnect the electrical path between the abnormal battery unit and the electronic device 103.

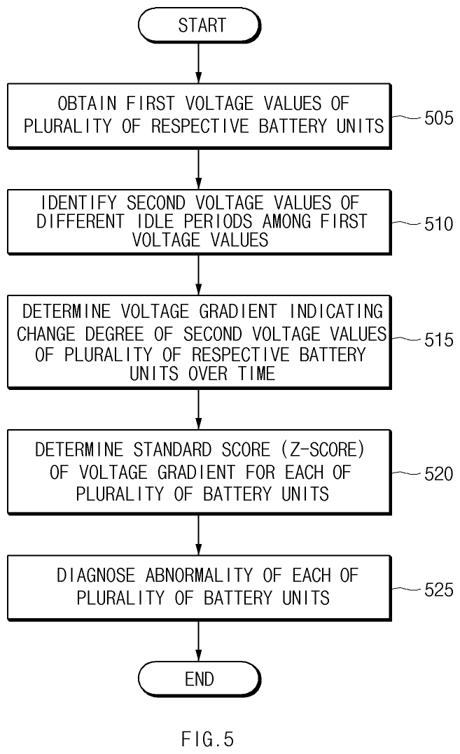

FIG. 5 is an operating flowchart of a battery diagnosis apparatus according to an embodiment. FIG. 5 will be described using components of FIG. 2.

The embodiment shown in FIG. 5 may be an example, and an order of operations according to various embodiments of the present disclosure may be different from that shown in FIG. 5, and some operations shown in FIG. 5 may be omitted, the order of the operations may be changed, or the operations may be merged.

Referring to FIG. 5, in operation 505, the battery diagnosis apparatus 101 may obtain the first voltage values of the plurality of respective battery units 111, 113, and 115. In an embodiment, the battery diagnosis apparatus 101 may obtain a plurality of voltage profiles respectively indicating voltage changes of the plurality of battery units 111, 113, and 115 over time. The battery diagnosis apparatus 101 may obtain the first voltage values based on the obtained plurality of voltage profiles.

In an embodiment, the battery diagnosis apparatus 101 may obtain the first voltage values of the plurality of respective battery unit 111, 113, and 115 through the electronic device 103 connected through a wired and/or wireless network.

In operation 510, the battery diagnosis apparatus 101 may identify the second voltage values in different idle periods from among the first voltage values obtained in operation 505. In an embodiment, the battery diagnosis apparatus 101 may set the different idle periods as periods having voltage values, current values, the amounts of charge, and/or the amounts of discharge in designated ranges. The battery diagnosis apparatus 101 may extract the different idle periods for each of the plurality of battery units 111, 113, and 115 from the obtained plurality of voltage profiles, and identify the second voltage values in the corresponding periods for the plurality of respective battery units 111, 113, and 115.

In an embodiment, the different idle periods may all be idle periods after different charging periods, or the different idle periods may all be idle periods after different discharging periods.

In operation 515, the battery diagnosis apparatus 101 may determine a voltage gradient of the second voltage values of the plurality of respective battery units 111, 113, and 115 over time. In an embodiment, the battery diagnosis apparatus 101 may determine average voltage values of different idle periods (e.g., idle periods after different charging periods or idle periods after different discharging periods) of each of the plurality of battery units 111, 113, and 115, based on the second voltage values. The battery diagnosis apparatus 101 may determine the voltage gradient based on the average voltage values.

In an embodiment, the battery diagnosis apparatus 101 may determine the voltage gradient based on the linear regression scheme. For example, the battery diagnosis apparatus 101 may determine the plurality of voltage gradients for the plurality of respective battery units 111, 113, and 115 based on the linear regression scheme by using all of the second voltage values of the plurality of respective battery units 111, 113, and 115 as input factors. In another example, the battery diagnosis apparatus 101 may determine the plurality of voltage gradients based on the linear regression scheme by using, as input factors, average voltage values in different idle periods of each of the plurality of battery units 111, 113, and 115.

In operation 520, the battery diagnosis apparatus 101 may determine a standard score of a voltage gradient for each of the plurality of battery units 111, 113, and 115 by using an average and a standard deviation of the plurality of voltage gradients one-to-one corresponding to the plurality of battery units 111, 113, and 115.

In operation 525, the battery diagnosis apparatus 101 may diagnose an abnormality of each of the plurality of battery units 111, 113, and 115. In an embodiment, the battery diagnosis apparatus 101 may diagnose the abnormality of each of the plurality of battery units 111, 113, and 115, based on the voltage gradient determined in operation 515 and the standard score determined in operation 520.

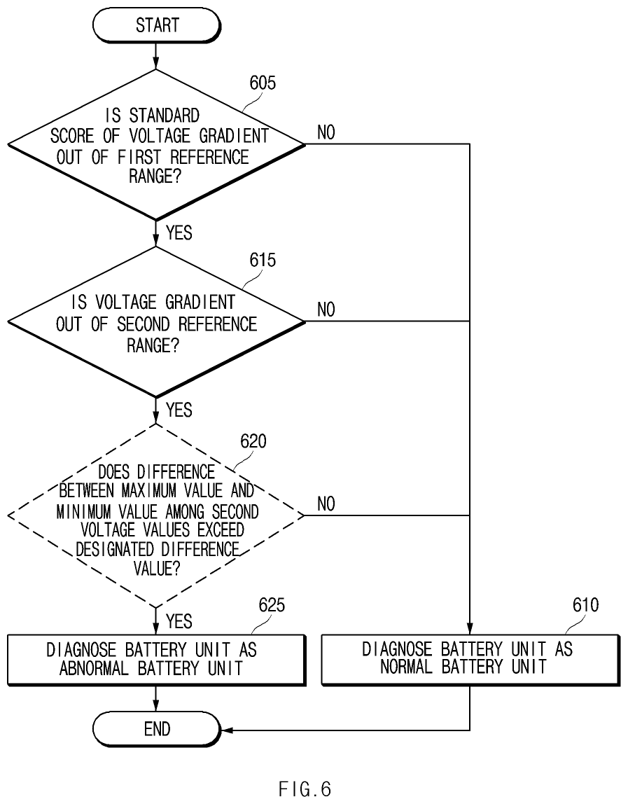

A more detailed description will be made of operation 525 of diagnosing the abnormality of each of the plurality of battery units 111, 113, and 115 by the battery diagnosis apparatus with reference to FIG. 6

FIG. 6 is an operating flowchart of a battery diagnosis apparatus according to an embodiment. FIG. 6 will be described using components of FIG. 2.

The embodiment shown in FIG. 6 may be an example, and an order of operations according to various embodiments of the present disclosure may be different from that shown in FIG. 6, and some operations shown in FIG. 6 may be omitted, the order of the operations may be changed, or the operations may be merged. For example, operation 620 may be omitted from FIG. 6.

In operation 605, the battery diagnosis apparatus 101 may identify whether the standard score of the voltage gradient of the battery unit 111, 113, or 115 is outside of the first reference range. For example, when different idle periods are idle periods after different charging periods, the battery diagnosis apparatus 101 may identify whether the standard score of the voltage gradient of the battery unit 111, 113, or 115 is greater than the first upper limit of the first reference range. In another example, when the different idle periods are idle periods after different discharging periods, the battery diagnosis apparatus 101 may identify whether the standard score of the voltage gradient of the battery unit 111, 113, or 115 is less than the first lower limit of the first reference range.

When the standard score of the voltage gradient of the battery unit 111, 113, or 115 is identified as being within the first reference range in operation 605 (‘NO’), the battery diagnosis apparatus 101 may diagnose the battery unit 111, 113, or 115 as a normal battery unit in operation 610.

When the standard score of the voltage gradient of the battery unit 111, 113, or 115 is identified as being outside of the first reference range in operation 605 (‘YES’), the battery diagnosis apparatus 101 may identify whether the voltage gradient of the battery unit 111, 113, or 115 is less than a second reference value in operation 615. For example, when different idle periods are idle periods after different charging periods, the battery diagnosis apparatus 101 may identify whether the voltage gradient of the battery unit 111, 113, or 115 is greater than the second upper limit of the second reference range. In another example, when the different idle periods are idle periods after different discharging periods, the battery diagnosis apparatus 101 may identify whether the voltage gradient of the battery unit 111, 113, or 115 is less than the second lower limit of the second reference range.

When the voltage gradient of the battery unit 111, 113, or 115 is identified as being within the second reference range in operation 615 (‘NO’), the battery diagnosis apparatus 101 may diagnose the battery unit 111, 113, or 115 as a normal battery unit in operation 610.

When the voltage gradient of the battery unit 111, 113, or 115 is identified as being outside of the second reference range in operation 615 (‘YES’), the battery diagnosis apparatus 101 may identify whether the difference between the maximum value and the minimum value among the second voltage values of the battery unit 111, 113, or 115 exceeds the designated difference value in operation 620.

When the difference between the maximum value and the minimum value among the second voltage values of the battery unit 111, 113, or 115 is identified as being less than the designated difference value in operation 620 (‘NO’), the battery diagnosis apparatus 101 may diagnose the battery unit 111, 113, or 115 as a normal battery unit in operation 610.

When the difference between the maximum value and the minimum value among the second voltage values of the battery unit 111, 113, or 115 is identified as exceeding the designated difference value in operation 620 (‘YES’), the battery diagnosis apparatus 101 may diagnose the battery unit 111, 113, or 115 as an abnormal battery unit in operation 625.

Terms such as “include”, “constitute” or “have” described above may mean that the corresponding component may be inherent unless otherwise stated, and thus should be construed as further including other components rather than excluding other components. All terms including technical or scientific terms have the same meanings as those generally understood by those of ordinary skill in the art to which the embodiments disclosed herein pertain, unless defined otherwise. The terms used generally like terms defined in dictionaries should be interpreted as having meanings that are the same as the contextual meanings of the relevant technology and should not be interpreted as having ideal or excessively formal meanings unless they are clearly defined in the present document.

1. A battery diagnosis apparatus comprising:
a processor; and
memory having instructions programmed thereon, wherein the instructions are configured to cause the processor to:
obtain respective first voltage values of a plurality of battery units;
identify second voltage values in different idle periods from among the first voltage values;
for each battery unit of the plurality of battery units:
determine a voltage gradient indicating a change degree of the second voltage values of the battery unitover time;
determine a Z-score of the voltage gradient for the battery unit based on an average and a standard deviation of the determined plurality of voltage gradients of the plurality of battery units; and
based on the Z-score of the battery unit being outside of a first reference range and the voltage gradient outside of a second reference range, diagnose the battery unit as an abnormal battery unit.

2. The battery diagnosis apparatus of claim 1, wherein the instructions are configured to cause the processor to:
for each battery unit of the plurality of battery units:
determine an average voltage value of the idle periods of the battery unit, based on the second voltage values of the battery unit; and
determine the voltage gradient based on the average voltage value.

3. The battery diagnosis apparatus of claim 1, wherein the instructions are configured to cause the processor to:
based on the battery unit having the Z-score greater than a first upper limit of the first reference range and the voltage gradient greater than a second upper limit of the second reference range, diagnose the battery unit as the abnormal battery unit, when the idle periods of the battery unit are after respective charging periods of the battery unit.

4. The battery diagnosis apparatus of claim 1, wherein the instructions are configured to cause the processor to:
based on the battery unit having the Z-score less than a first lower limit of the first reference range and the voltage gradient less than a second lower limit of the second reference range, diagnose the battery unit as the abnormal battery unit, when the idle periods of the battery unit are after respective discharging periods of the battery unit.

5. The battery diagnosis apparatus of claim 1, wherein the instructions are configured to cause the processor to diagnose the battery unit as the abnormal battery unit, based on a difference between a maximum value and a minimum value of the second voltage values of the battery unit being greater than a designated difference value.

6. The battery diagnosis apparatus of claim 1, wherein the instructions are configured to cause the processor to set the idle periods as periods of time for which respective ones of the plurality of battery units have one or more of voltage values, current values, amounts of charge, or amounts of discharge within respective designated ranges.

7. The battery diagnosis apparatus of claim 1, wherein the instructions are configured to cause the processor to, for each battery unit diagnosed as abnormal, perform an abnormality processing function,
wherein the abnormality processing function comprises a notification function or a short-circuit function.

8. A battery diagnosis method comprising:
obtaining respective first voltage values of a plurality of respective battery units;
identifying second voltage values in different idle periods from among the first voltage values;
for each battery unit of the plurality of battery units:
determining a voltage gradient indicating a change degree of the second voltage values of the battery unit over time;
determining a Z-score of the voltage gradient for the battery unit based on an average and a standard deviation of the determined plurality of voltage gradients of the plurality of battery units;
based on the Z-score outside of a first reference range and the voltage gradient outside of a second reference range, diagnosing the battery unit as an abnormal battery unit.

9. The battery diagnosis method of claim 8, wherein the determining of the voltage gradient comprises:
for each battery unit of the plurality of battery units:
determining an average voltage value of the idle periods of the battery unit, based on the second voltage values of the battery unit; and
determining the voltage gradient based on the average voltage value.

10. The battery diagnosis method of claim 8, wherein, when the idle periods of the battery unit are after charging periods of the battery unit, diagnosing the battery unit as an abnormal battery unit is based on the Z-score being greater than a first upper limit of the first reference range and the voltage gradient being greater than a second upper limit of the second reference range.

11. The battery diagnosis method of claim 8, wherein, when the idle periods of the battery unit are after discharging periods of the battery unit, diagnosing the battery unit as an abnormal battery unit is based on the Z-score being less than a first lower limit of the first reference range and the voltage gradient being less than a second lower limit of the second reference range.

12. The battery diagnosis method of claim 8, wherein the diagnosing of the battery unit as abnormal is based on a difference between a maximum value and a minimum value of the second voltage values of the battery unit being greater than a designated difference value.

13. The battery diagnosis method of claim 8, further comprising setting the idle periods as periods of time for which respective ones of the plurality of battery units have one or more of voltage values, current values, amounts of charge, or amounts of discharge within respective designated ranges.

14. The battery diagnosis method of claim 8, further comprising, for each battery unit diagnosed as abnormal, performing an abnormality processing function,
wherein the abnormality processing function comprises a notification function or a short-circuit function.

15. A non-transitory computer-readable storage medium having stored therein instructions that, when executed by one or more processors, cause the one or more processors to perform operations comprising:
obtaining respective first voltage values of a plurality of respective battery units;
identifying second voltage values in different idle periods from among the first voltage values;
for each battery unit of the plurality of battery units:
determining a voltage gradient indicating a change degree of the second voltage values of the battery unit over time;
determining a Z-score of the voltage gradient for the battery unit based on an average and a standard deviation of the determined plurality of voltage gradients of the plurality of battery units; and
based on the Z-score outside of a first reference range and the voltage gradient outside of a second reference range, diagnosing the battery unit as an abnormal battery unit.

16. The non-transitory computer-readable storage medium of claim 15, wherein the determining of the voltage gradient comprises:
for each battery unit of the plurality of battery units:
determining an average voltage value of the idle periods of the battery unit, based on the second voltage values of the battery unit; and
determining the voltage gradient based on the average voltage value.

17. The non-transitory computer-readable storage medium of claim 15, wherein, when the idle periods of the battery unit are after charging periods of the battery unit, diagnosing the battery unit as an abnormal battery unit is based on the Z-score being greater than a first upper limit of the first reference range and the voltage gradient being greater than a second upper limit of the second reference range.

18. The non-transitory computer-readable storage medium of claim 15, wherein, when the idle periods of the battery unit are after discharging periods of the battery unit, diagnosing the battery unit as an abnormal battery unit is based on the Z-score being less than a first lower limit of the first reference range and the voltage gradient being less than a second lower limit of the second reference range.

19. The non-transitory computer-readable storage medium of claim 15, wherein the diagnosing of the battery unit as abnormal is based on a difference between a maximum value and a minimum value of the second voltage values of the battery unit being greater than a designated difference value.

20. The non-transitory computer-readable storage medium of claim 15, further comprising setting the idle periods as periods of time for which respective ones of the plurality of battery units have one or more of voltage values, current values, amounts of charge, or amounts of discharge within respective designated ranges.
